(19) United States
(12) Patent Application Publication
(10) Pub. No.: US 2026/0205078 A1
(43) Pub. Date: Jul. 16, 2026

(54) Operational amplifier with enhanced input slew rate

(71) Applicant: NOVATEK Microelectronics Corp., Hsin-Chu (TW)

(72) Inventor: Yen-Cheng Cheng, Hsinchu City (TW)

(73) Assignee: NOVATEK Microelectronics Corp., Hsin-Chu (TW)

(21) Appl. No.: 19/017,748

(22) Filed: Jan. 12, 2025

(51) Int. Cl. H03F 3/45

(52) U.S. Cl. CPC H03F 3/45269; H03F 2200/372

(57) ABSTRACT

An operational amplifier includes an input stage, a first switch, a second switch and a third switch. The input stage includes a current source and a first differential input pair. The first differential input pair includes a first input transistor and a second input transistor. The first input transistor has a gate terminal. The second input transistor has a gate terminal coupled to an output terminal of the operational amplifier. The first switch is coupled between an input terminal of the operational amplifier and the gate terminal of the first input transistor. The second switch is coupled between the gate terminal of the first input transistor and the gate terminal of the second input transistor. The third switch is coupled to the current source and deployed on a current path of the first differential input pair.

### BACKGROUND OF THE INVENTION

### 1. Field of the Invention

The present invention relates to an operational amplifier, and more particularly, to a design technique for an operational amplifier to enhance the input slew rate.

### 2. Description of the Prior Art

An operational amplifier is a basic circuit component frequently used in analog integrated circuits (ICs) such as a source driver or data driver of a display panel. Under the design and application for a high resolution and low offset (i.e., small deviation of data voltages) source driver IC, the operational amplifier, which is used as an output buffer in the source driver circuit (abbreviated as a source operational amplifier, SOP, hereinafter), is requested to comply with both the bandwidth and speed requirements.

However, due to excessively large parasitic capacitance in the differential input pairs of the SOP, a bottleneck is generated such that the output speed of the SOP cannot be increased. This bottleneck is mainly caused by the RC delay generated at the input terminal of the SOP. In general, the differential input pairs in the SOP should have a larger number and/or a greater size, to realize the differential difference amplifier (DDA) application and also achieve the low offset. Such a large number/size of the differential input pairs will generate considerable parasitic capacitance at the input terminal, thereby limiting the input slew rate of the SOP. Thus, there is a need for improvement over the prior art.

### SUMMARY OF THE INVENTION

It is therefore an objective of the present invention to provide a novel operational amplifier to achieve an enhanced input slew rate, so as to solve the abovementioned problems.

An embodiment of the present invention discloses an operational amplifier, which comprises an input stage, a first switch, a second switch and a third switch. The input stage comprises a current source and a first differential input pair. The first differential input pair comprises a first input transistor and a second input transistor. The first input transistor has a gate terminal. The second input transistor has a gate terminal coupled to an output terminal of the operational amplifier. The first switch is coupled between an input terminal of the operational amplifier and the gate terminal of the first input transistor. The second switch is coupled between the gate terminal of the first input transistor and the gate terminal of the second input transistor. The third switch is coupled to the current source and deployed on a current path of the first differential input pair.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the value of an input voltage of an SOP under different parasitic capacitance.

FIG. 2 is a schematic diagram of an SOP and a DAC in a source driver according to an embodiment of the present invention.

FIG. 3 illustrates that the parasitic capacitance at the positive input terminal is decreased when the SOP is in the enhanced mode.

FIG. 4A and FIG. 4B are schematic diagrams of a switch implementation for realizing the switching of the differential input pairs according to an embodiment of the present invention.

FIG. 5 and FIG. 6 illustrate detailed implementations of the SOP according to embodiments of the present invention.

FIG. 7A and FIG. 7B are waveform diagrams of the signals associated with the SOP shown in FIG. 5.

FIGS. 8A-8D illustrate the detailed operations of the SOP during the voltage transition.

FIG. 9 is a schematic diagram of an SOP according to an embodiment of the present invention.

FIG. 10 illustrates that the SOP operates in the enhanced mode.

FIG. 11 illustrates that the SOP operates in the normal mode.

FIG. 12A and FIG. 12B are schematic diagrams of a switch implementation with multiple current sources in the input stage of another SOP according to an embodiment of the present invention.

FIG. 13A and FIG. 13B illustrate a detailed implementation of the SOP according to an embodiment of the present invention.

### DETAILED DESCRIPTION

As mentioned above, the source operation amplifier (SOP) included in the source driver should have an enough operational speed to drive a display panel, especially for a display panel with high resolution and high frame rate. The operational speed of the SOP is mainly determined from the slew rate of the SOP. In order to achieve the bandwidth and speed requirements, the SOP should have sufficient output slew rate and input slew rate. The output slew rate is determined from the driving capability of the SOP itself. The input slew rate is determined from the driving capability of the front-end digital-to-analog converter (DAC) and the parasitic capacitance and resistance between the DAC and the SOP. The present invention provides a design technique for enhancing the input slew rate of the SOP under the predetermined driving capability of the DAC.

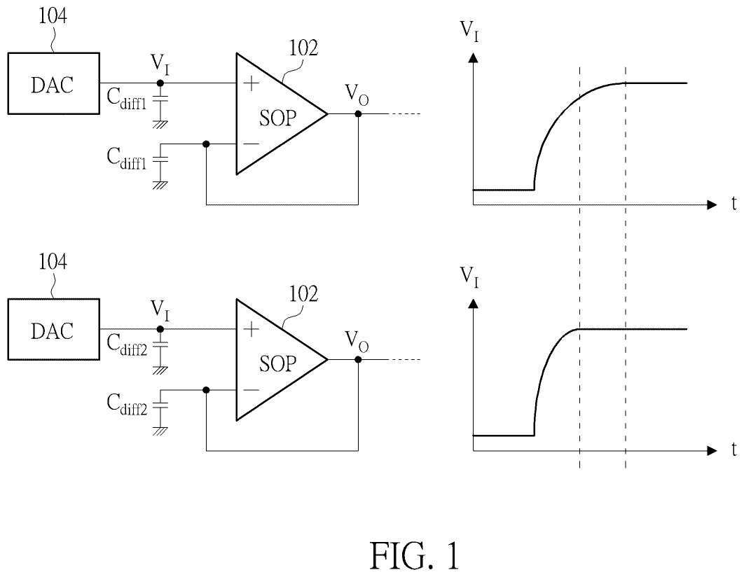

FIG. 1 illustrates the value of an input voltage V_{I} of an SOP 102 under different parasitic capacitance. The SOP 102 may receive a display data voltage as the input voltage V_{I} from a DAC 104, and correspondingly output an output voltage V_{O} to drive a display panel (not illustrated). The SOP 102 may serve as an output buffer of the source driver, where the negative input terminal of the SOP 102 may be connected to its output terminal to realize the output buffer. The SOP 102 may receive the input voltage V_{I} from the DAC 104 through its positive input terminal.

The operational speed of the SOP 102 may be determined according to the input slew rate, which is further determined from the parasitic capacitance and resistance between the DAC 104 and the SOP 102. The DAC 104 is requested to capture the correct data voltage from a resistor string, and thus a considerable resistance is unavoidable. The parasitic capacitance may come from the differential input pairs of the SOP 102. For example, as shown in FIG. 1, the differential input pairs may generate parasitic capacitances C_{diff1} and C_{diff2} at the input terminals of the SOP 102.

In this example, the parasitic capacitance C_{diff1} is greater than the parasitic capacitance C_{diff2}. Therefore, in the case where there is a larger parasitic capacitance C_{diff1}, the input slew rate may be lower, causing that the input voltage V_{I} rises with a slower speed, which in turn decreases the output speed of the SOP 102. On the other hand, with a smaller parasitic capacitance C_{diff2}, the input slew rate and the operational speed of the SOP 102 may be improved.

According to the present invention, partial differential input pairs of the SOP may be switched to be coupled to the output terminal, to be driven by the SOP itself, so that the parasitic capacitance of these differential input pairs may be charged through the powerful driving capability of the SOP. In such a situation, the equivalent parasitic capacitance driven by the DAC output may be decreased, thereby increasing the input slew rate.

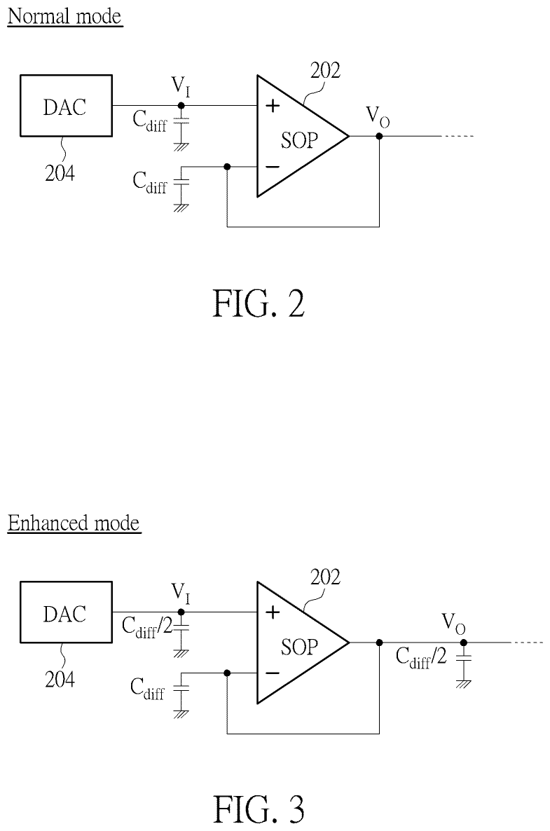

FIG. 2 is a schematic diagram of an SOP 202 and a DAC 204 in a source driver according to an embodiment of the present invention. Similarly, the SOP 202 receives an input voltage V_{I} from the DAC 204, and operates as an output buffer to generate and output an output voltage V_{O}. The differential input pairs of the SOP 202 may generate a parasitic capacitance C_{diff} at each input terminal. The SOP 202 is configured to operate in a normal mode and an enhanced mode. In the normal mode, the SOP 202 is connected normally and thus the parasitic capacitance C_{diff} at each input terminal has a normal value. When the SOP 202 is in the enhanced mode, there may be partial differential input pairs switched to the output terminal; hence, the parasitic capacitance at the positive input terminal that receives the input voltage V_{I} may be decreased. For example, as shown in FIG. 3, supposing that one half of the differential input pairs are switched to the output terminal, the parasitic capacitance at the positive input terminal is decreased by half, i.e., C_{diff}/2. This will decrease the output loading of the DAC 204 by half, thereby enhancing the input slew rate of the SOP 202. The other half parasitic capacitance C_{diff}/2 is switched to the output terminal of the SOP 202 to be driven and charged by the SOP 202 itself.

In an embodiment, since the SOP 202 is configured to drive a display panel by outputting a display data voltage, the SOP 202 may enter the enhanced mode when the display data voltage is updated. After the SOP 202 is charged to the target level of the new display data voltage, it will leave the enhanced mode and enter the normal mode.

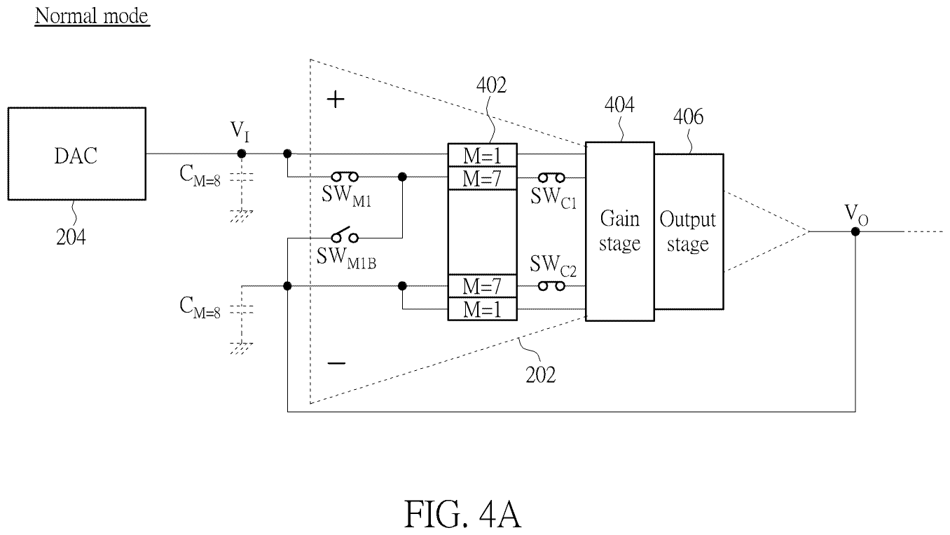

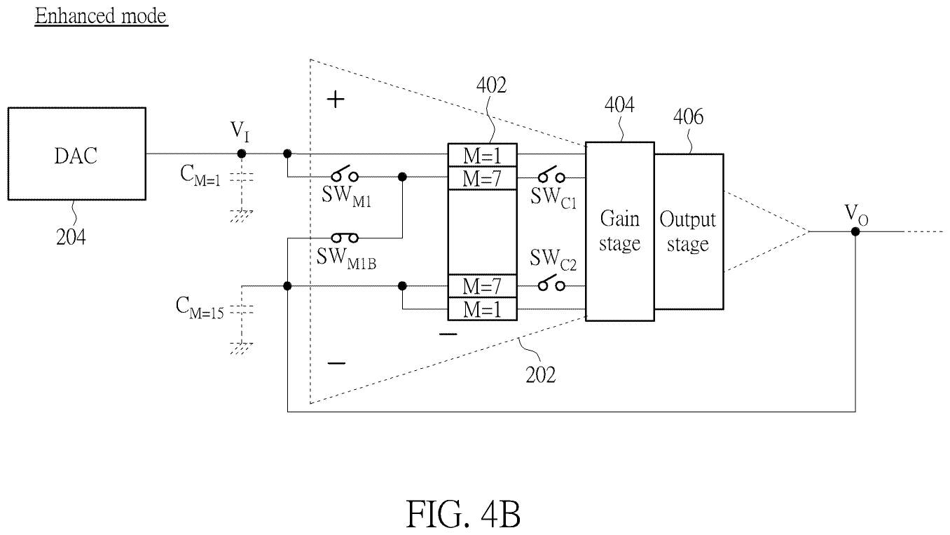

FIGS. 4A and 4B are schematic diagrams of a switch implementation for realizing the switching of the differential input pairs according to an embodiment of the present invention, where FIG. 4A illustrates the SOP 202 in the normal mode and FIG. 4B illustrates the SOP 202 in the enhanced mode. The SOP 202 includes an input stage 402, a gain stage 404 and an output stage 406. The input stage 402 may include several differential input pairs, and in this embodiment, there are 8 differential input pairs, denoted by M=8.

In order to control the switching operations of the differential input pairs, the SOP 202 may further include mode control switches SW_{M1} and SW_{M1B} and current switches SW_{C1} and SW_{C2}. Among the 8 differential input pairs, 7 of them (M=7) may be switched between the input terminal and the output terminal of the SOP 202, and the other 1 (M=1) may be always coupled to the input terminal of the SOP 202 to receive the input voltage V_{I}. The mode control switches SW_{M1} and SW_{M1B} and the current switches SW_{C1} and SW_{C2} are coupled to the 7 switchable differential input pairs to control their switching operations.

As shown in FIG. 4A, in the normal mode, the mode control switch SW_{M1} is on and the mode control switch SW_{M1B} is off; hence, the 7 switchable differential input pairs at the positive input terminal are coupled to the input terminal of the SOP 202. In such a situation, the parasitic capacitance at the input terminal of the SOP 202 is generated from 8 input transistors to have a value equal to C_{M=8}. Since the 8 input transistors at the negative input terminal are always coupled to the output terminal of the SOP 202, the parasitic capacitance at the output terminal of the SOP 202 may also be equal to C_{M=8}.

As shown in FIG. 4B, in the enhanced mode, the mode control switch SW_{M1} is off and the mode control switch SW_{M1B} is on; hence, the 7 switchable differential input pairs at the positive input terminal are switched to be coupled to the output terminal of the SOP 202. In such a situation, the parasitic capacitance at the input terminal of the SOP 202 is only generated from one input transistor to have a value equal to C_{M=1}, which is quite small and thereby significantly increases the input slew rate of the SOP 202. These differential input pairs are switched to be coupled to the output terminal of the SOP 202, and thus the parasitic capacitance at the output terminal of the SOP 202 will have a larger value C_{M=15}, which is equivalently generated from 15 input transistors. The larger parasitic capacitance at the output terminal may be easily charged through the powerful driving capability of the SOP 202 without evidently influencing the overall slew rate.

In the normal mode as shown in FIG. 4A, the current switches SW_{C1} and SW_{C2} are both on, allowing the current to be normally supplied to each differential input pair. When the SOP 202 enters the enhanced mode as shown in FIG. 4B, the current switches SW_{C1} and SW_{C2} may be turned off; hence, the current in the input stage will be entirely supplied to the one differential input pair for receiving the input voltage V_{I}. Note that the input slew rate is negatively correlated to the parasitic capacitance, and also positively correlated to the current for charging the parasitic capacitance. This charging current may be provided from the tail current for the differential input pairs. If the tail current is equally divided to each differential input pair, when partial differential input pairs are switched to the output terminal, both the parasitic capacitance and the charging current will be decreased, such that the input slew rate may not be improved. In order to solve this problem, it is preferable to turn off the current switches SW_{C1} and SW_{C2} when the SOP 202 enters the enhanced mode, allowing the entire tail current to flow to the differential input pair(s) that used to receive the input voltage V_{I}. In other words, the current switches SW_{C1} and SW_{C2} may be switched with the mode control switches SW_{M1} and SW_{M1B}. As a result, the differential input pair(s) may still have sufficient charging current for the parasitic capacitance in the enhanced mode.

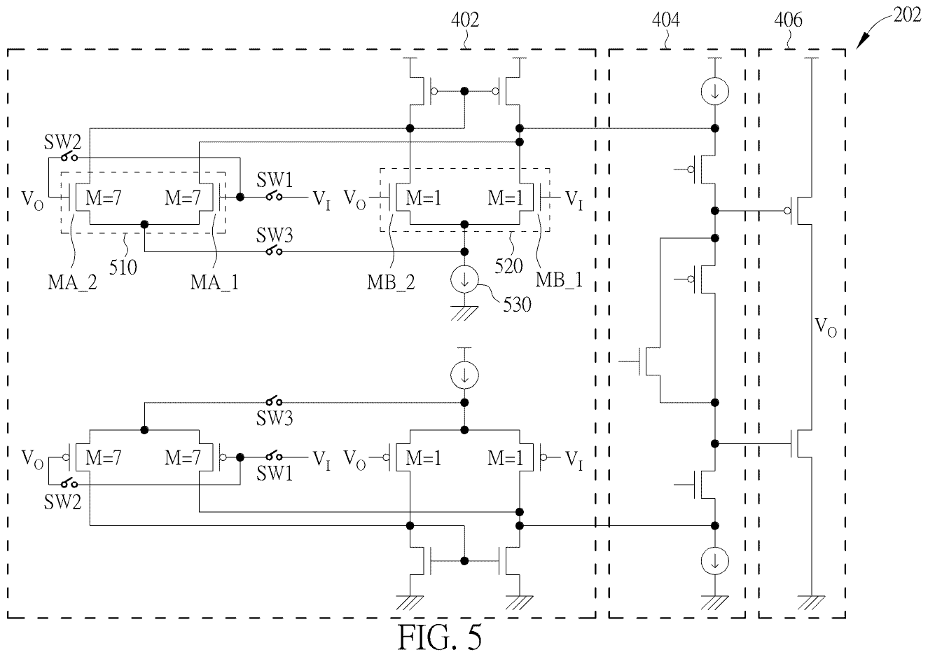

FIG. 5 illustrates a detailed implementation of the SOP 202 according to an embodiment of the present invention. FIG. 5 shows a transistor level in the SOP 202, where the input stage 402 includes an NMOS input stage and a PMOS input stage. As mentioned above, the SOP 202 may be implemented in the source driver for driving a display panel, and thus the output data voltage is requested to have a full range. In such a situation, the input stage 402 should include both the NMOS input stage and the PMOS input stage, so that it is able to receive the full-range input voltage V_{I}.

In this embodiment, since the NMOS input stage and the PMOS input stage have a corresponding structure, in the following descriptions, the NMOS input stage will be taken as an example to illustrate the operations of the input stage 402. Those skilled in the art may also infer the operations of the PMOS input stage accordingly.

In another embodiment, if there is no requirement for full-range output, the input stage may contain only one of the NMOS input stage and the PMOS input stage, and this should also belong to the scope of the present invention.

In detail, the input stage 402 includes at least one differential input pair 510 configured to be switched between the input terminal and the output terminal of the SOP 202, and at least one differential input pair 520 configured to be always coupled to the input terminal of the SOP 202. The implementations of differential input pairs shown in FIG. 5 are similar to those shown in FIGS. 4A and 4B. For example, the differential input pair 520 may include 1 branch (M=1), while the differential input pair 510 may include 7 branches (M=7); or equivalently, the differential input pair 520 may be one differential input pair of which the transistor size is equal to 1 unit, and the differential input pair 510 may be one differential input pair of which the transistor size is equal to 7 units; or equivalently, there may be 1 differential input pair in the differential input pair 520, and 7 differential input pairs with the same transistor size in the differential input pair 510.

The input stage 402 may further include a current source 530 for supplying currents to the differential input pairs 510 and 520. The switches SW1-SW3, which may be included in the input stage 402 or coupled to the input stage 402, is used for controlling the switching of the differential input pair 510.

As shown in FIG. 5, the differential input pair 510 includes a pair of input transistors MA_1 and MA_2. The gate terminal of the input transistor MA_1 is configured to be switchable between the input terminal and the output terminal of the SOP 202, and the gate terminal of the input transistor MA_2 is configured to be always coupled to the output terminal of the SOP 202. The differential input pair 520 includes a pair of input transistors MB_1 and MB_2. The gate terminal of the input transistor MB_1 is configured to be always coupled to the input terminal of the SOP 202 to receive the input voltage V_{I}, and the gate terminal of the input transistor MB_2 is configured to be always coupled to the output terminal of the SOP 202. In this embodiment, the differential input pair 510 is switched between different operation modes to reduce the input parasitic capacitance, and the differential input pair 520 is always connected normally to maintain the normal operations of the SOP 202.

In order to control the switching of the differential input pair 510, the switches SW1 and SW2 may be implemented as the mode control switches SW_{M1} and SW_{M1B} shown in FIGS. 4A and 4B. The switch SW1 is coupled between the input terminal of the SOP 202 and the gate terminal of the input transistor MA_1. The switch SW2 is coupled between the gate terminal of the input transistor MA_1 and the gate terminal of the input transistor MA_2. In addition, the switch SW3 may be implemented as any of the current switches SW_{C1} and SW_{C2} shown in FIGS. 4A and 4B. In this embodiment, the switch SW3 is coupled between the differential input pair 510 and the current source 530. Therefore, the switch SW3 may control the current source 530 to supply a current to the differential input pair 510 or not. Since the differential input pairs 510 and 520 share the same current source 530, the switch SW3 may control the current of the current source 530 to be supplied to the differential input pairs 510 and/or 520.

The PMOS input stage in the input stage 402 includes similar switches SW1-SW3, which may be deployed and controlled in the same way as in the NMOS input stage, and will not be detailed herein.

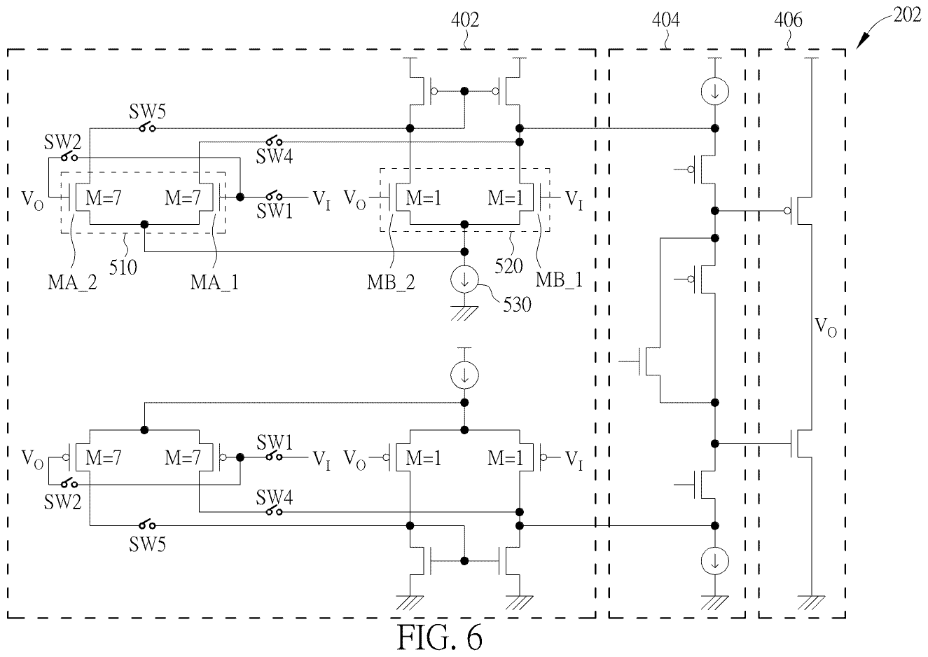

Note that the current switch may be coupled to the current source 530 and deployed on a current path of the differential input pair 510, and the switch SW3 shown in FIG. 5 is merely an exemplary implementation of the current switch. In another embodiment, the current switch may be coupled between the switchable differential input pair and the gain stage. For example, as shown in FIG. 6, there are two switches SW4 and SW5 coupled between the differential input pair 510 and the gain stage 404, to replace the usage of the switch SW3. More specifically, the switch SW4 is coupled between the input transistor MA_1 and the gain stage 404, and the switch SW5 is coupled between the input transistor MA_2 and the gain stage 404. The switches SW4 and SW5 may also block the current flowing through the differential input pair 510 in the enhanced mode, to make the differential input pair 520 have sufficient current to charge the parasitic capacitance at the input terminal of the SOP 202.

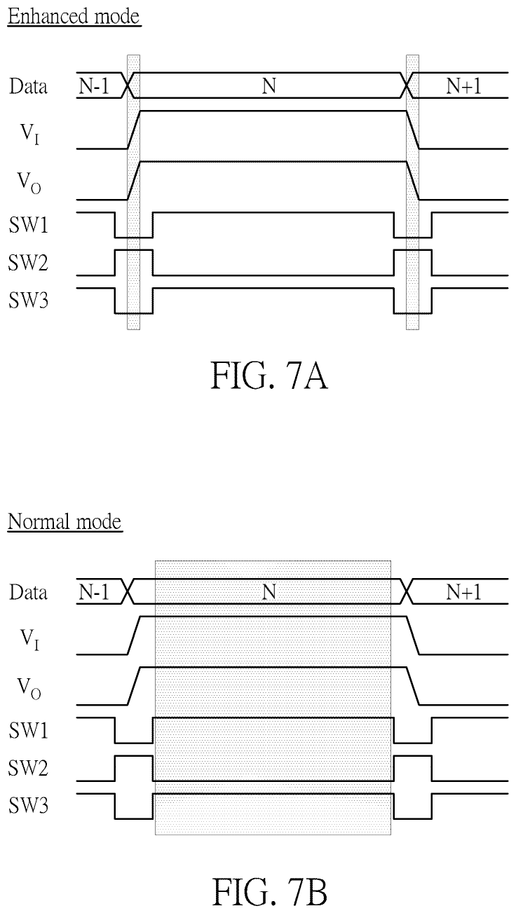

As mentioned above, the SOP 202 may be switched between the enhanced mode and the normal mode. FIGS. 7A and 7B are waveform diagrams of the signals associated with the SOP 202 shown in FIG. 5, where the input voltage V_{I}, the output voltage V_{O}, and the control signals for the switches SW1-SW3 are shown. The display data is also shown in FIGS. 7A and 7B to facilitate the illustrations.

As shown in FIG. 7A, the SOP 202 may be in the enhanced mode during the transition of the display data (e.g., from N−1 to N or from N to N+1), where the input voltage V_{I} and the output voltage V_{O} transit their level and thus the parasitic capacitances of the SOP 202 should be charged. At this moment, the SOP 202 enters the enhanced mode to enhance the input slew rate, where the switch SW1 is turned off and the switch SW2 is turned on, so as to switch partial differential input pairs to the output terminal and thereby decrease the input parasitic capacitance of the SOP 202. In this embodiment, since only one of the 8 differential input pairs is configured to receive the input voltage V_{I}, the parasitic capacitance at the input terminal may be reduced to approximately ⅛ of the original, which will significantly increase the input slew rate. The parasitic capacitance of the input transistors that switched to be coupled to the output terminal of the SOP 202 is charged through the driving capability of the SOP 202. Since the SOP 202 is configured to drive the tremendous loading on the display panel, it usually has a powerful driving capability which is sufficient to charge this parasitic capacitance.

Simultaneously, the switch SW3 is off to cut off the current that flows to the switchable differential input pair(s) (e.g., 510). Therefore, the current will be entirely supplied to the non-switched differential input pair(s) (e.g., 520) so that the current charging capability for the input parasitic capacitance will not be reduced.

As shown in FIG. 7B, when the input voltage V_{I} and the output voltage V_{O} reach their target level, the SOP 202 may return to the normal mode. In the normal mode, the switch SW1 is on and the switch SW2 is off, and thus the differential input pairs are connected normally. Simultaneously, the switch SW3 is on to conduct the current to the switchable differential input pair(s).

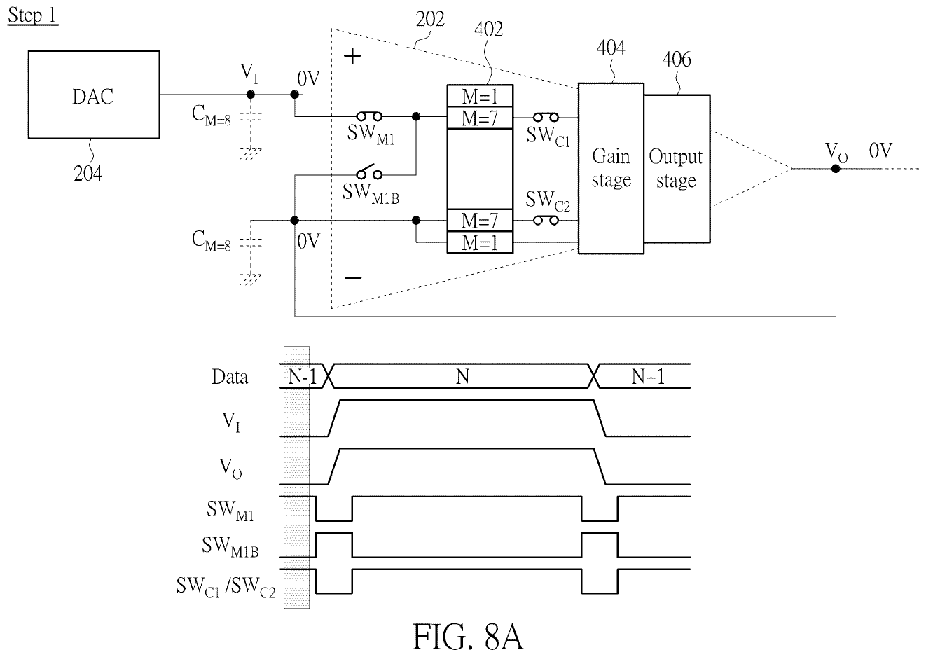

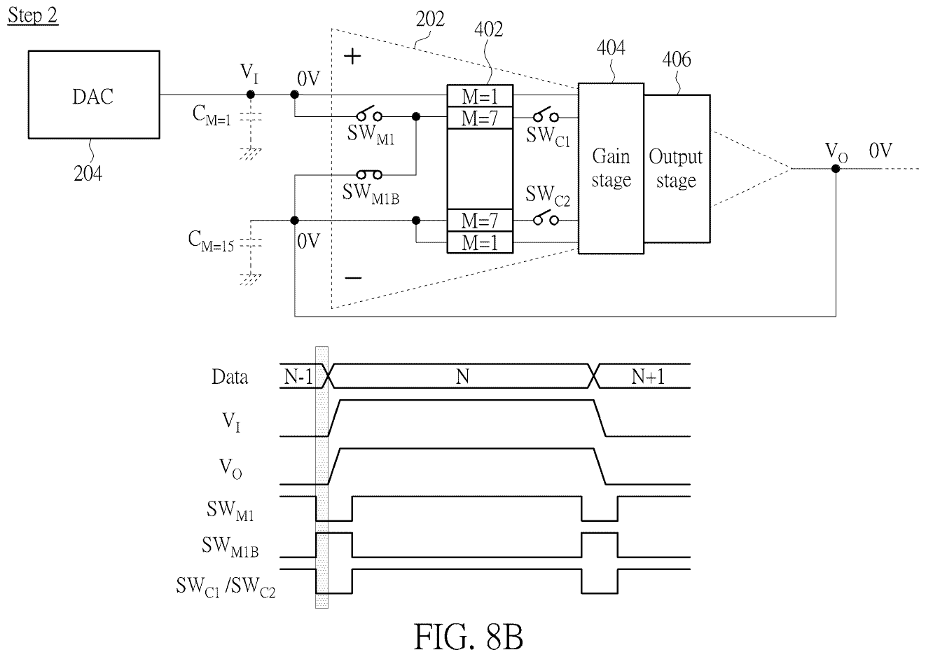

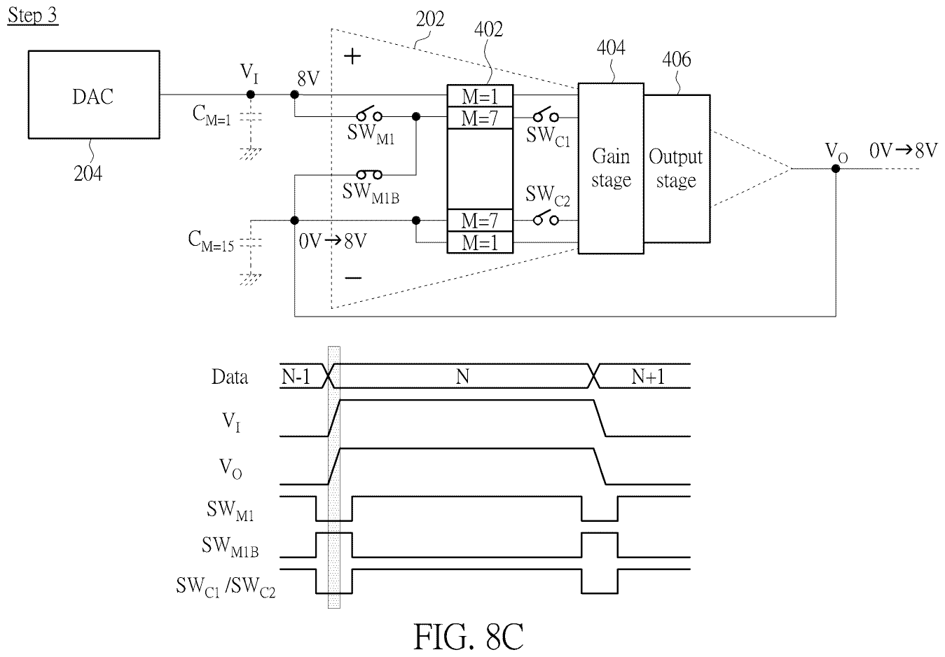

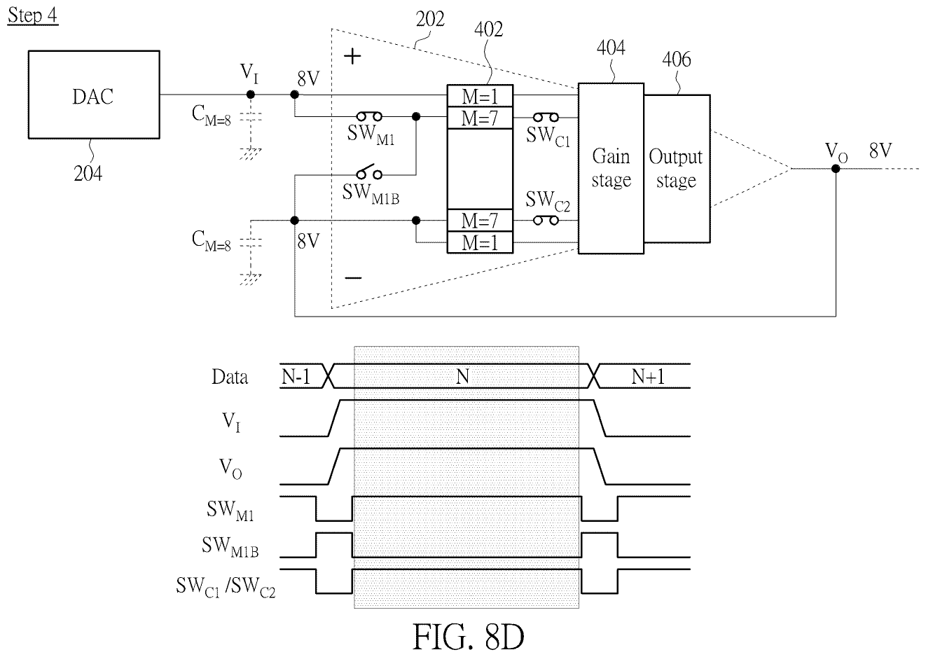

FIGS. 8A-8D illustrate the detailed operations of the SOP 202 during the voltage transition (e.g., from display data N−1 to N). FIG. 8A shows Step 1, where the SOP 202 is in a steady state of a display line period for outputting the display data N−1, which may correspond to the data voltage 0V. At this moment, the SOP 202 operates in the normal mode, where the mode control switch SW_{M1} is on, the mode control switch SW_{M1B} is off, and the current switches SW_{C1} and SW_{C2} are on.

FIG. 8B shows Step 2. In this step, before the display data changes, the SOP 202 enters the enhanced mode, where the mode control switch SW_{M1} is off, the mode control switch SW_{M1B} is on, and the current switches SW_{C1} and SW_{C2} are off. At this moment, the parasitic capacitance at the input terminal of the SOP 202 (i.e., the output terminal of the DAC 204) is decreased (e.g., from C_{M=8} to C_{M=1}).

FIG. 8C shows Step 3. In this step, the display data changes from N−1 to N, which leads to a transition of the data voltage from 0V to 8V. With the decreased parasitic capacitance at the input terminal, the input slew rate of the SOP 202 may be enhanced, so that the input voltage V_{I} may rise rapidly. The parasitic capacitance of those differential input pairs switched to the output terminal is charged by the output voltage V_{O}, which may also rise rapidly due to the powerful driving capability of the SOP 202.

FIG. 8D shows Step 4. In this step, after the data voltage reaches its target level, the SOP 202 may return to the normal mode, where the mode control switch SW_{M1} is on, the mode control switch SW_{M1B} is off, and the current switches SW_{C1} and SW_{C2} are on. Therefore, the SOP 202 will enter a steady state and output the stable output voltage V_{O}.

Note that FIGS. 8A-8D illustrate the voltage transition from 0V to 8V based on the display data changing from N−1 to N. During another voltage transition period (such as the display data from N to N+1), the SOP 202 may operate in a similar manner to be switched to output a new display data voltage. The detailed operations could be easily inferred by those skilled in the art and will be omitted herein.

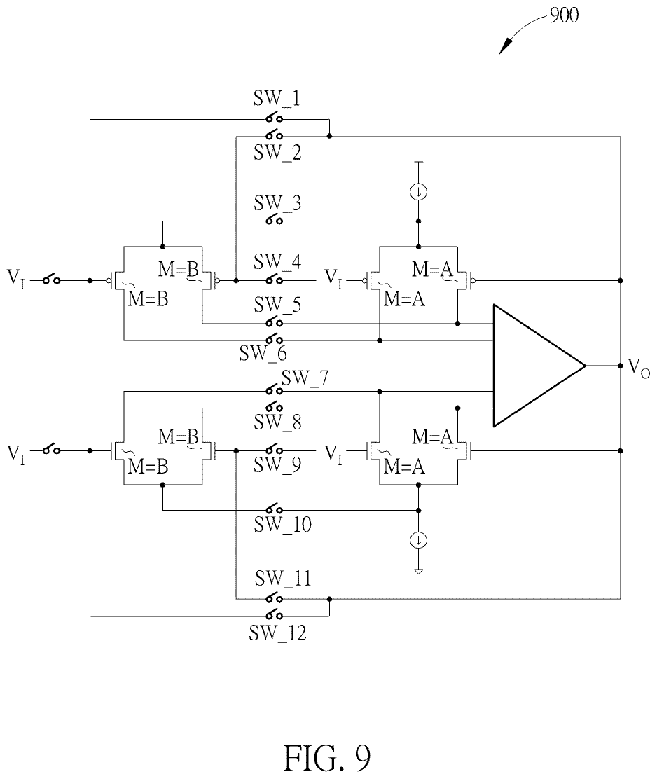

FIG. 9 is a schematic diagram of an SOP 900 according to an embodiment of the present invention, where the detailed structure of the input stage of the SOP 900 is shown. The SOP 900 has another implementation of switches, and may also receive an input voltage V_{I} to generate an output voltage V_{O}. Similarly, in order to receive the full-range input voltage V_{I} and generate the full-range output voltage V_{O}, the input stage of the SOP 900 has an NMOS input stage and a PMOS input stage. As shown in FIG. 9, the SOP 900 includes 12 switches SW_1-SW_12, where the switches SW_1-SW_6 are used to control the PMOS input stage and the switches SW_7-SW_12 are used to control the NMOS input stage. In the following descriptions, the PMOS input stage is taken as an example to illustrate the detailed operations of the input stage. Those skilled in the art should be able to infer the operations of the NMOS input stage in a similar manner.

As shown in FIG. 9, in the input stage, there are A differential input pairs (M=A) coupled to the input terminal and the output terminal normally, and B differential input pairs (M=B) with input transistors connected switchable between the input terminal and the output terminal.

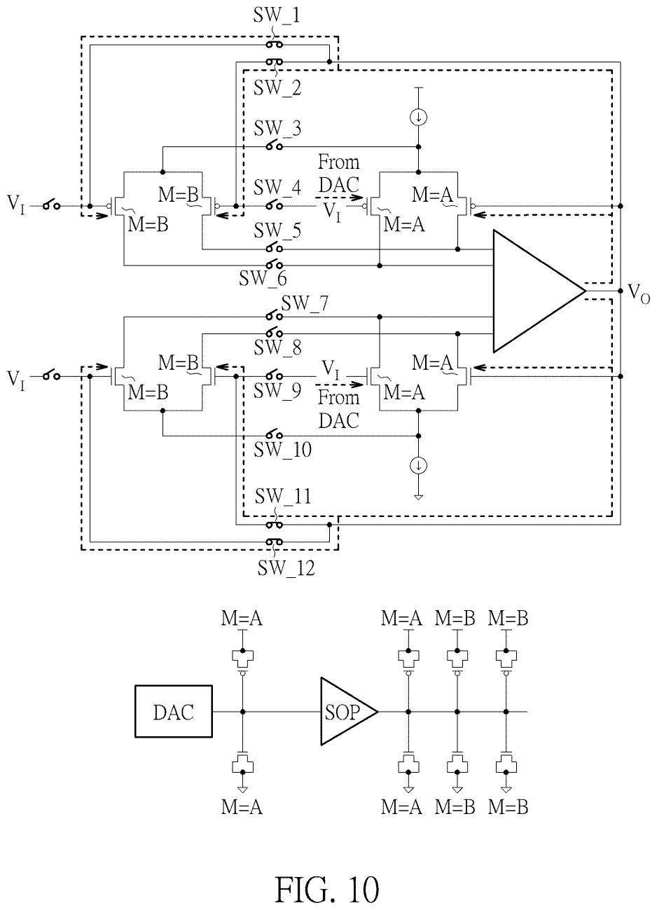

FIG. 10 illustrates that the SOP 900 operates in the enhanced mode, where the switches SW_1 and SW_2 are on, and the switches SW_3-SW_6 are off. In such a situation, the B differential input pairs are switched to the output terminal of the SOP 900 and thus driven/charged by the output driving capability of the SOP 900. The DAC only needs to drive/charge the parasitic capacitance of A input transistor (M=A) in A differential input pairs. Therefore, the input slew rate may be enhanced.

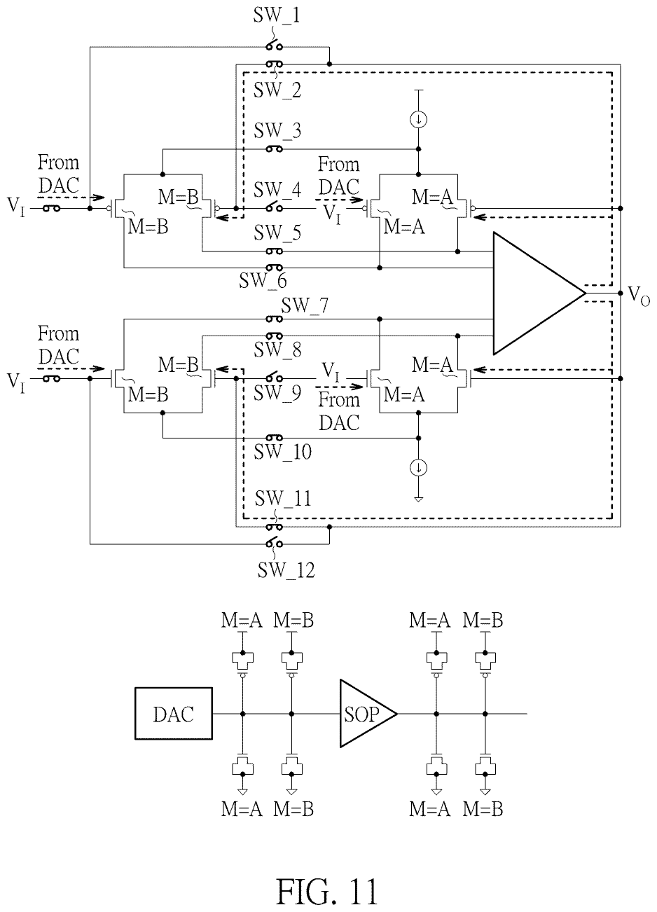

FIG. 11 illustrates that the SOP 900 operates in the normal mode, where the switches SW2, SW3, SW5 and SW6 are on, and the switches SW1 and SW4 are off. In such a situation, the B differential input pairs are switched to the input terminal of the SOP 900, which means that these differential input pairs are connected normally. The DAC and the SOP drive their corresponding input transistors (M=A and M=B).

Please note that the present invention aims at providing a novel input stage structure of an SOP to achieve an enhanced input slew rate. Those skilled in the art may make modifications and alterations accordingly. For example, in the above embodiments, the ratio of differential input pairs switched to be coupled to the output terminal of the SOP is merely an example. In fact, as long as the input stage of the SOP is deployed in an appropriate manner to allocate at least one differential input pair to be switchable between the input terminal and the output terminal and also allocate at least one differential input pair to be always connected to the input terminal to receive the input voltage, the related implementation should belong to the scope of the present invention.

In addition, in various embodiments, the SOP may apply a differential difference amplifier (DDA) operation and perform interpolation by receiving a high input voltage and a low input voltage from the DAC. As long as the input stage of the SOP is deployed in an appropriate manner to allocate at least one differential input pair to be connected switchable between the input terminals and the output terminal and also allocate at least one differential input pair to be always connected to an input terminal to receive the high input voltage or the low input voltage, the related implementation should belong to the scope of the present invention.

Also note that the circuit structure of the SOP in the above embodiments is merely an exemplary implementation. For example, FIGS. 5 and 6 show a basic structure of the gain stage and the output stage, but their actual structures may be adjusted or modified according to system requirements. In addition, in the above embodiments, all the differential input pairs in the input stage share the same current source, of which the current is allocated to the normally connected differential input pair(s) and the switchable differential input pair(s) in an appropriate manner. In another embodiment, the current source of the input stage may be implemented in another manner.

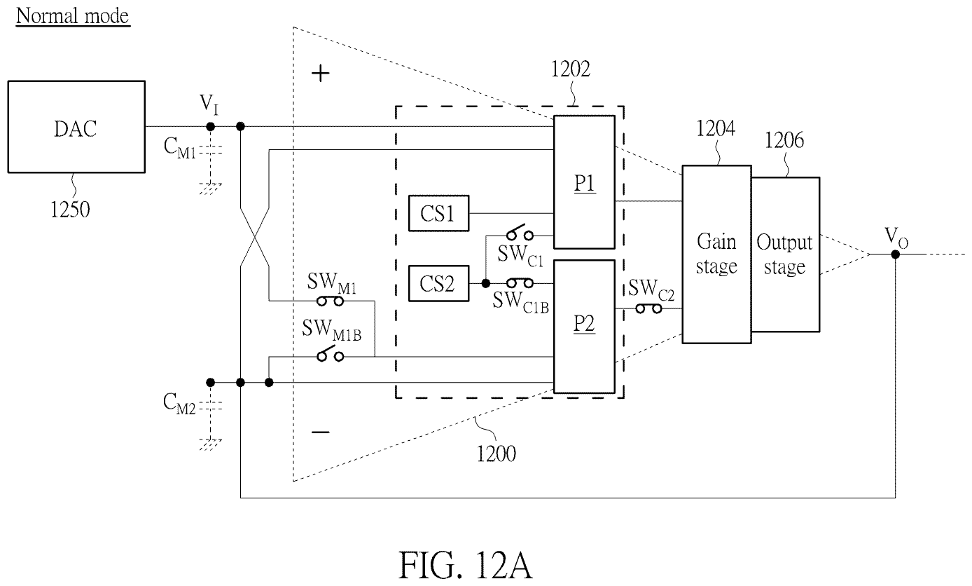

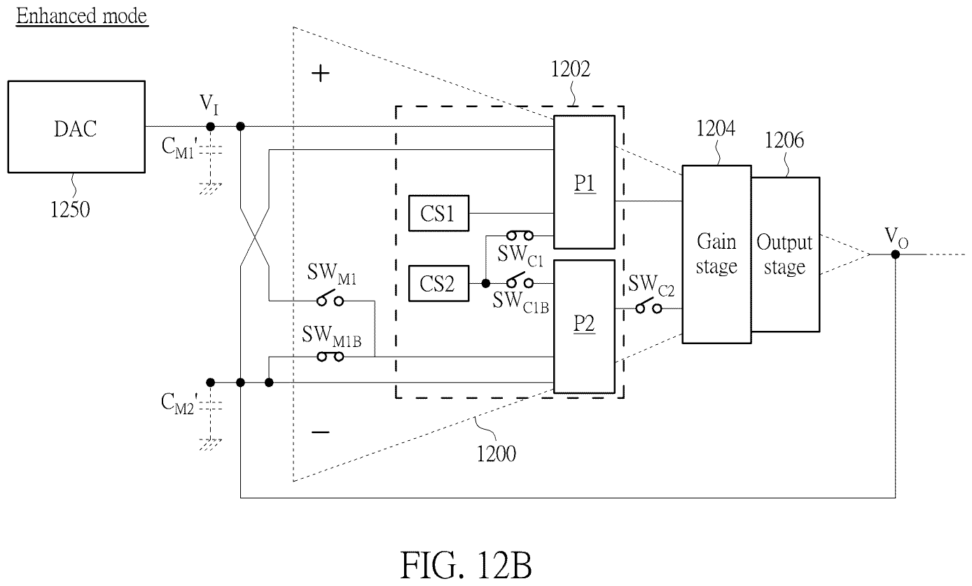

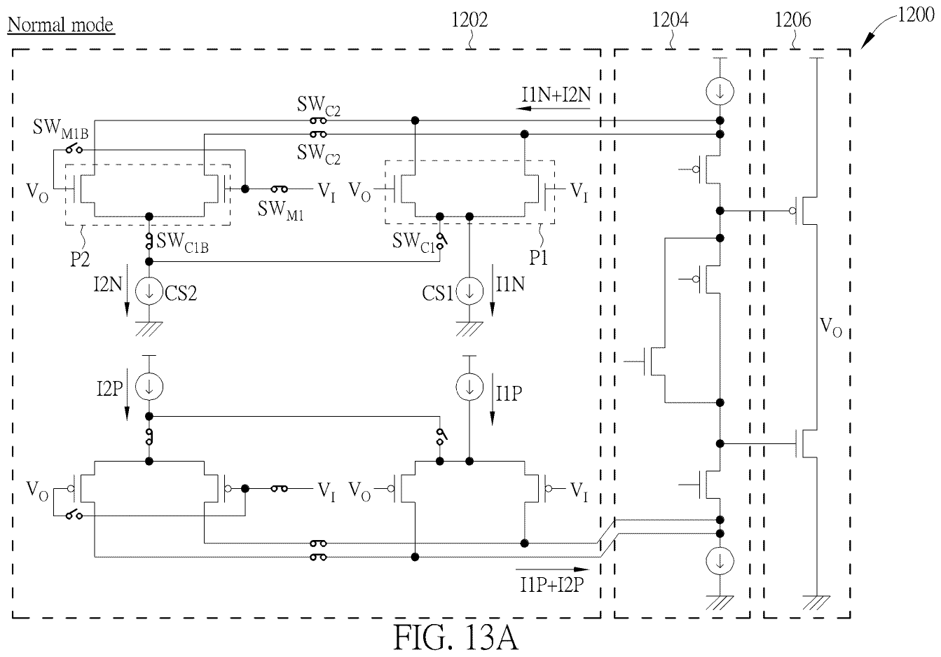

FIGS. 12A and 12B are schematic diagrams of a switch implementation with multiple current sources in the input stage of another SOP 1200 according to an embodiment of the present invention, where FIG. 12A illustrates the SOP 1200 in the normal mode and FIG. 12B illustrates the SOP 1200 in the enhanced mode. Similarly, the SOP 1200 includes an input stage 1202, a gain stage 1204 and an output stage 1206. The SOP 1200 may receive an input voltage V_{I} from a DAC 1250, and correspondingly generate and output an output voltage V_{O}.

The input stage 1202 includes multiple differential input pairs, among which two differential input pairs P1 and P2 are shown in FIGS. 12A and 12B. The input stage 1202 may further include two current sources CS1 and CS2. The current source CS1 is configured to supply a current to the differential input pair P1, and the current source CS2 is configured to supply a current to the differential input pair P2 in the normal mode. In this embodiment, the differential input pair P1 is normally connected, which means that an input terminal of the differential input pair P1 is always coupled to the input terminal of the SOP 1200, and another input terminal of the differential input pair P1 is always coupled to the output terminal of the SOP 1200. The differential input pair P2 is connected switchable between the input terminal and the output terminal of the SOP 1200, which means that an input terminal of the differential input pair P2 is always coupled to the output terminal of the SOP 1200, and another input terminal of the differential input pair P2 may be switched between the input terminal and the output terminal of the SOP 1200.

In order to realize the switching operations, the input stage 1202 may further include (or may be coupled to) mode control switches SW_{M1} and SW_{M1B}. The mode control switch SW_{M1} is coupled between the differential input pair P2 and the input terminal of the SOP 1200, and the mode control switch SW_{M1B} is coupled between the differential input pair P2 and the output terminal of the SOP 1200. There are also several current switches SW_{C1}, SW_{C1B} and SW_{C2} coupled to the switchable differential input pair P2 for controlling the current output of the current source CS2. More specifically, the current switch SW_{C1} is coupled between the differential input pair P1 and the current source CS2, the current switch SW_{C1B} is coupled between the differential input pair P2 and the current source CS2, and the current switch SW_{C2} is coupled between the differential input pair P2 and the gain stage 1204.

In the normal mode as shown in FIG. 12A, the mode control switch SW_{M1} is on and the mode control switch SW_{M1B} is off; hence, the differential input pair P2 is connected normally. In such a situation, the parasitic capacitance at the input terminal of the SOP 1200 may have a value equal to C_{M1}, which is generated from the differential input pairs P1 and P2. The parasitic capacitance at the output terminal of the SOP 1200 may have a value equal to C_{M2}. In addition, the current switches SW_{C1B} and SW_{C2} are on and the current switch SW_{C1} is off, so that the current source CS2 may normally supply a current to the differential input pair P2.

In the enhanced mode as shown in FIG. 12B, the mode control switch SW_{M1} is off and the mode control switch SW_{M1B} is on; hence, the input terminal of the differential input pair P2 originally coupled to the input terminal of the SOP 1200 is switched to be coupled to the output terminal of the SOP 1200. In such a situation, the parasitic capacitance at the input terminal of the SOP 1200 may have a value equal to C_{M1}′, which is generated only from the differential input pair P1. Therefore, the parasitic capacitance C_{M1}′ will be smaller than the parasitic capacitance C_{M1}. The parasitic capacitance at the output terminal of the SOP 1200 may have a value equal to C_{M2}′, which is greater than the parasitic capacitance C_{M2} since more input transistors are switched to be coupled to the output terminal of the SOP 1200 in the enhanced mode.

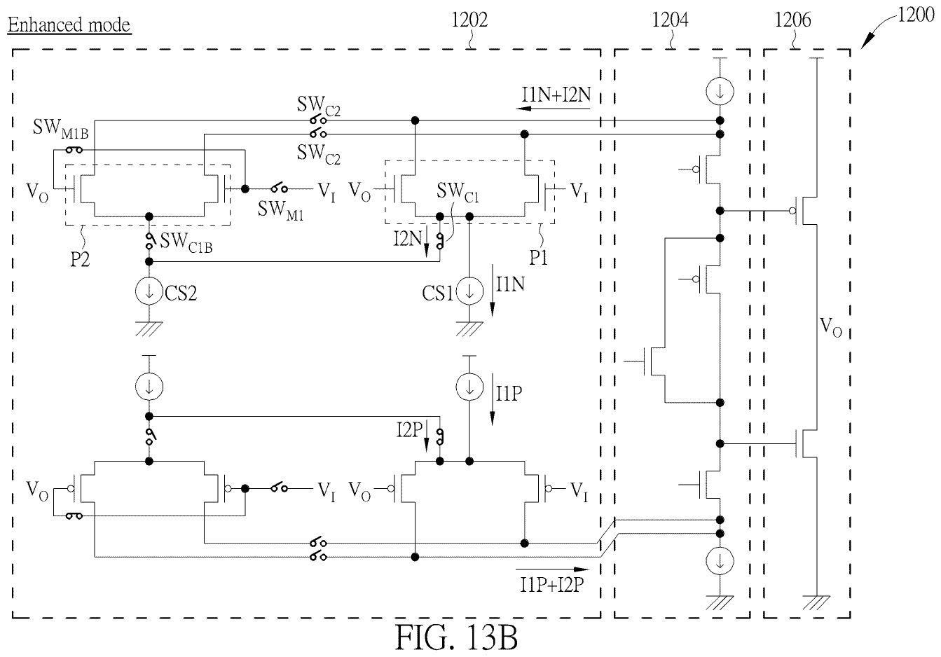

FIGS. 13A and 13B illustrate a detailed implementation of the SOP 1200 according to an embodiment of the present invention, where a transistor level in the SOP 1200 is shown. FIG. 13A illustrates the SOP 1200 in the normal mode and FIG. 13B illustrates the SOP 1200 in the enhanced mode. The implementation may be realized in the NMOS input stage, the PMOS input stage, or both. The operations of each circuit module of the SOP 1200 are identical to those described in the above paragraphs, and will not be repeated herein.

Different from the implementation as shown in FIGS. 5 and 6, in this embodiment, there are two current sources CS1 and CS2 respectively used for the differential input pairs P1 and P2. Supposing that the switching structure shown in FIGS. 12A and 12B is implemented in the NMOS input stage, the current source CS1 may supply a current I1N, and the current source CS2 may supply a current I2N.

As shown in FIG. 13A, in the normal mode, both the differential input pairs P1 and P2 are connected normally and receive the input voltage V_{I}. With the control of the current switches SW_{C1}, SW_{C1B} and SW_{C2}, the current I1N is supplied to the differential input pair P1 and the current I2N is supplied to the differential input pair P2. The summation of the currents I1N and I2N is sourced from the gain stage 1204. Similarly, in the PMOS input stage, the summation of the currents I1P and I2P is sunk to the gain stage 1204.

As shown in FIG. 13B, in the enhanced mode, the differential input pair P1 is connected normally, but the differential input pair P2 is switched to be coupled to the output terminal of the SOP 1200. That is, the gate terminals of both input transistors of the differential input pair P2 are commonly coupled to the output terminal of the SOP 1200. With the control of the current switches SW_{C1}, SW_{C1B} and SW_{C2}, the current I2N is switched to be supplied to the differential input pair P1. In such a situation, the same current value I1N+I2N is sourced from the gain stage 1204 in the enhanced mode, and this current may be used to charge the input parasitic capacitance of the SOP 1200. Therefore, the charging current for the input parasitic capacitance is not reduced when the SOP 1200 enters the enhanced mode. Similarly, in the PMOS input stage, the current value I1P+I2P is used for charging the input parasitic capacitance in the enhanced mode.

To sum up, the present invention provides a circuit structure of the input stage of an SOP. The SOP may be in an enhanced mode and a normal mode. The enhanced mode provides a higher input slew rate for the SOP. The SOP includes several mode control switches to switch the SOP between the enhanced mode and the normal mode. More specifically, the mode control switches may control the input transistors in several differential input pairs originally connected to the input terminal of the SOP to be switched to the output terminal of the SOP, to enhance the input slew rate by decreasing the parasitic capacitance at the input terminal of the SOP. The SOP further includes one or more current switches to control the currents to be conducted to the switchable differential input pair(s) or the non-switched differential input pair(s), so as not to reduce the charging current for the parasitic capacitance at the input terminal when the SOP is in the enhanced mode. The SOP may enter the enhanced mode when the display data changes, so that the input voltage and the output voltage of the SOP may reach their target level with a faster speed under the enhanced slew rate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An operational amplifier, comprising:
an input stage, comprising:
a current source; and
a first differential input pair, comprising:
a first input transistor, having a gate terminal; and
a second input transistor, having a gate terminal coupled to an output terminal of the operational amplifier;
a first switch, coupled between an input terminal of the operational amplifier and the gate terminal of the first input transistor;
a second switch, coupled between the gate terminal of the first input transistor and the gate terminal of the second input transistor; and
a third switch, coupled to the current source and deployed on a current path of the first differential input pair.

2. The operational amplifier of claim 1, wherein the third switch is coupled between the first differential input pair and the current source.

3. The operational amplifier of claim 1, wherein the third switch is coupled between the first input transistor and a gain stage of the operational amplifier, and the operational amplifier further comprises:
a fourth switch, coupled between the second input transistor and the gain stage.

4. The operational amplifier of claim 1, wherein the third switch is coupled between the second input transistor and a gain stage of the operational amplifier, and the operational amplifier further comprises:
a fourth switch, coupled between the first input transistor and the gain stage.

5. The operational amplifier of claim 1, wherein the third switch controls the current source to supply a current to the first differential input pair or not.

6. The operational amplifier of claim 1, wherein the input stage further comprises:
a second differential input pair, coupled to the current source and comprising:
a third input transistor, having a gate terminal coupled to the input terminal of the operational amplifier; and
a fourth input transistor, having a gate terminal coupled to the output terminal of the operational amplifier.

7. The operational amplifier of claim 6, wherein the third switch controls a current of the current source to be supplied to the first differential input pair or the second differential input pair.

8. The operational amplifier of claim 7, wherein the third switch is off to control the current source to not supply the current to the first differential input pair when the operational amplifier is in an enhanced mode.

9. The operational amplifier of claim 6, further comprising:
a fourth switch, coupled between the second differential input pair and the current source;
wherein the fourth switch is on when the third switch is off.

10. The operational amplifier of claim 1, wherein the first switch is off, the second switch is on, and the third switch is off in a first operation mode, and the first switch is on, the second switch is off, and the third switch is on in a second operation mode.
